(19) United States
(12) Patent Application Publication
(10) Pub. No.: US 2006/0211232 A1
(43) Pub. Date: Sep. 21, 2006

(54) Method for Manufacturing Gold Bumps

(76) Inventors: Mei-Jen Liu, Tao-Yuan Hsien (TW); Yu-Ting Lai, Chia-I City (TW); Kuang-Shin Lee, Hsin-Chu City (TW); Ming-Tsung Tung, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/907,005

(22) Filed: Mar. 16, 2005

(51) Int. Cl. H01L 21/44

(52) U.S. Cl. 438/613; 438/614; 438/686

(57) ABSTRACT

A method for manufacturing gold bumps includes providing a substrate including a patterned protective layer, which exposes at least a bonding pad, on a surface, covering a photo resist on the surface of the substrate, performing a photolithography process to pattern the photo resist for exposing a portion of the protective layer and the bonding pad, removing a portion of the protective layer, removing the photo resist, and performing a gold bumping process. The resulting thickness of the protective layer covering the bonding pad is smaller than the resulting thickness of the protective layer covering the substrate.

### BACKGROUND OF INVENTION

1. Field of the Invention

The present invention relates to a method for manufacturing gold bumps, and more particularly, to a method for manufacturing gold bumps, which is capable of improving a step height of a gold bump border and increasing package quality.

2. Description of the Prior Art

Accompanying the progress of movable electronic devices, a several different types of packages, which are light, thin, and small, are developed. The flip chip ball grid array (FCBGA) package is one example. The flip chip ball grid array package configuration differs from conventional ones particularly in that the semiconductor chip is mounted in an upside-down manner on a substrate and is electrically coupled to the same by means of gold bumps provided on the active surface of the semiconductor chip.

The idea of the flip chip ball grid array package configuration is that gold bumps are first formed on bonding pads of a chip and then an anisotropic conductive film or silver paste is utilized to adhere the gold bumps to a package substrate. Since no bonding wires are required, the overall size of the flip chip ball grid array package can be made very compact compared to conventional types of package configurations. Therefore, the flip chip package is capable of increasing the circuit density and increasing performance of circuitry.

Please refer to FIG. 1. FIG. 1 is a schematic diagram of a gold bump 20 bonding with a package substrate 22 according to the prior art. As shown in FIG. 1, a die 10 surface includes a bonding pad 12, a silicon oxide layer 14, and a silicon nitride layer 16. The silicon oxide layer 14 and the silicon nitride layer 16, covering the die 10 surface and a portion of the bonding pad 12 surface in sequence, form a protective layer 18. Furthermore, the die 10 includes a gold bump 20 disposed on the corresponding bonding pad 12. Since the protective layer 18 has a step height on the bonding pad 12 border, the gold bump 20 border also has a complementary step height. While the gold bump 20 bonds with the package substrate 22, a portion of an anisotropic conductive film 24 applied between the gold bump 20 and the package substrate 22 may not connect the gold bump 20 and the package substrate 22 because of the step height of the gold bump 20 border.

As mentioned above, if the step height of the gold bump 20 border is too large, the package quality will be influenced seriously. However, if there is no step height of the gold bump 20 border, the anisotropic conductive film 24 will not gather on the gold bump 20 surface properly. There are two methods according to the prior art for improving the above problem. The first method deposits the protective layer 18 more thinly on the die 10, but this method will reduce the product reliability substantially. The second method shrinks the bonding pad 12, however this method will cause the anisotropic conductive film 24 to not spread uniformly.

### SUMMARY OF INVENTION

It is therefore a primary objective of the present invention to provide a method for manufacturing gold bumps to solve the above-mentioned problems.

According to the above objective, a method for manufacturing gold bumps of the present invention includes providing a substrate including a patterned protective layer, which exposes at least a bonding pad, on a surface, covering a photo resist on the surface of the substrate, utilizing a mask to perform a photolithography process for patterning the photo resist and exposing a portion of the protective layer and the bonding pad, removing a portion of the protective layer to make a thickness of the protective layer covering the bonding pad smaller than a thickness of the protective layer covering the substrate surface, removing the photo resist, and utilizing the mask to perform a gold bumping process.

Since the present invention is capable of shrinking the step height of the gold bump border, the bonding result between the gold bump and the package substrate is better and thus the package quality is increased substantially. Moreover, the present invention does not need to add an additional mask and increase the cost of the additional mask.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of a gold bump bonding with a package substrate according to the prior art.

FIG. 2 to FIG. 7 are schematic diagrams for illustrating a method for manufacturing a gold bump according to a first embodiment of the present invention.

FIG. 8 to FIG. 10 are schematic diagrams for illustrating a method for manufacturing gold bumps according to a second embodiment of the present invention.

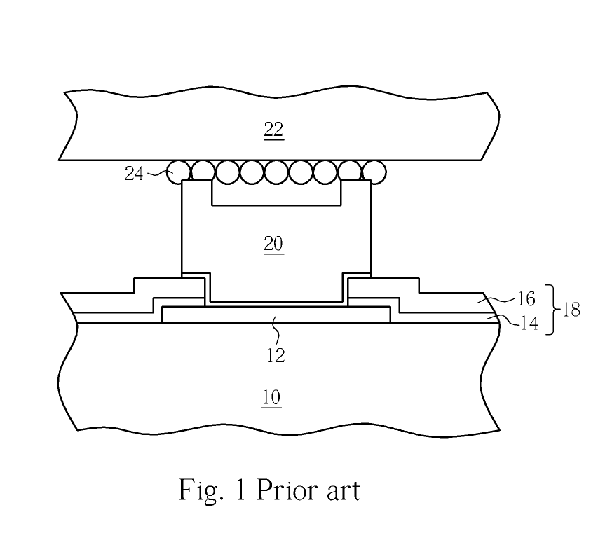

### DETAILED DESCRIPTION

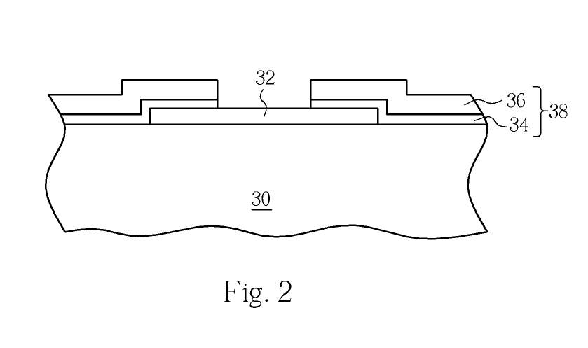

Please refer to FIG. 2 to FIG. 7. FIG. 2 to FIG. 7 are schematic diagrams for illustrating a method for manufacturing a gold bump 48 according to a first embodiment of the present invention. As shown in FIG. 2, a substrate 30 is provided. The substrate 30 surface includes at least a bonding pad 32, a silicon oxide layer 34, and a silicon nitride layer 36. The bonding pad 32 is made of aluminum. The silicon oxide layer 34 and the silicon nitride layer 36 form a patterned protective layer 38 covering a portion of the bonding pad 32 surface and exposing a portion of the bonding pad 32 surface. The silicon oxide layer 34 and the silicon nitride layer 36 are deposited on the substrate 30 and the bonding pad 32 surface respectively. In the present invention, a thickness of the protective layer 38, composed of the silicon oxide layer 34 and the silicon nitride layer 36, covering the bonding pad 32 is equivalent to the thickness of the protective layer 38 covering the substrate 30 surface.

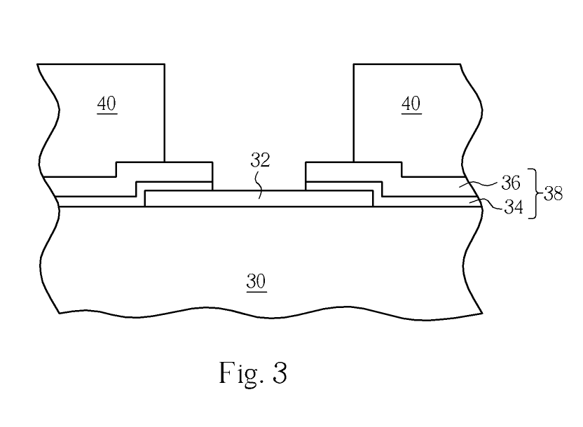

As shown in FIG. 3, a first photo resist 40 covers the substrate 30 surface by a spin-on coating. Through a photolithography process such as exposing, developing, and so forth, the first photo resist 40 is patterned by a mask (not shown) to expose a portion of the protective layer 38 surface and the bonding pad 32 surface.

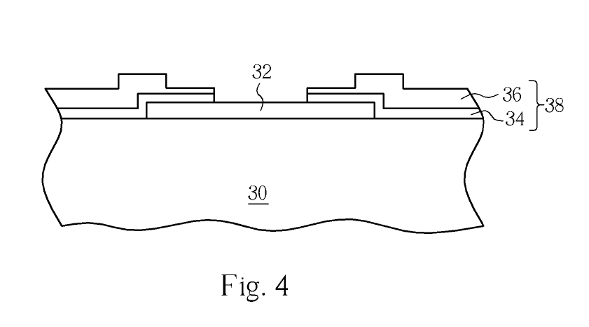

As shown in FIG. 4, utilizing the first photo resist 40 as a mask, a portion of the protective layer 38 is removed by an etch process such as a wet etch process, dry etch process, and so forth. For example, a portion of the silicon nitride layer 36 is removed vertically. Therefore, a thickness of the protective layer 38 covering the bonding pad 32 is smaller than a thickness of the protective layer 38 covering the substrate 30 surface. Afterward the first photo resist 40 is removed.

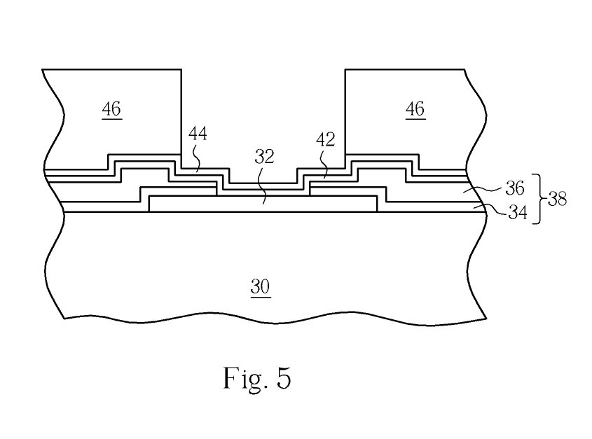

As shown in FIG. 5, a titanium tungsten alloy (TiW alloy) layer 42 and a gold (Au) 44 layer are formed on the protective layer 38 and the bonding pad 32 surface respectively by an under bump metallurgy process. A person skilled in the art will appreciate that the under bump metal layer should not be limited to the above combination. Then a second photo resist 46 is formed on the substrate 30 surface by a spin-on coating. Through a photolithography process such as exposing, developing, and so forth, the second photo resist 46 is patterned by the mask mentioned before to expose a portion of the gold layer 44 surface.

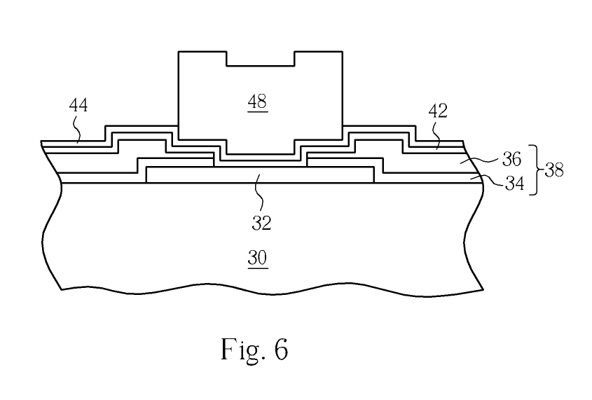

As shown in FIG. 6, utilizing the second photo resist 46 as a mask, a gold bump 48 is formed on portions of the gold layer 44 surface that are not covered by the second photo resist 46 by an electroplate process. The gold bump 48, disposed corresponding to the bonding pad 32, is made of gold. Then the second photo resist 46 is removed. Thereof, a step height of the gold bump 48 border of the present invention is smaller than a step height of the gold bump border of the prior art. Therefore, the present invention is capable of increasing the bonding result between the gold bump 48 and a package substrate (not shown).

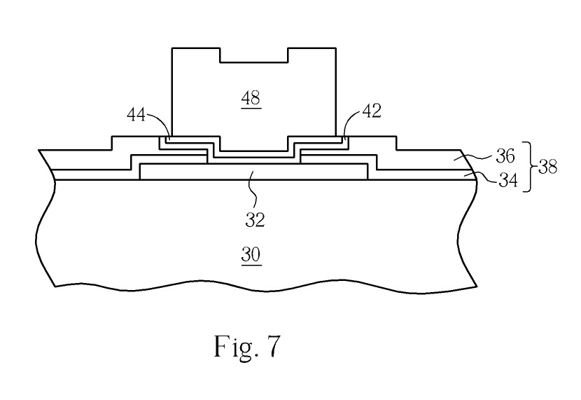

As shown in FIG. 7, portions of the gold layer 44 and the titanium tungsten alloy layer 42, which are not covered by the gold bump 48, are removed in sequence by etch processes. Then a thermal anneal process is performed to complete the method for manufacturing the gold bump 48 of the present invention.

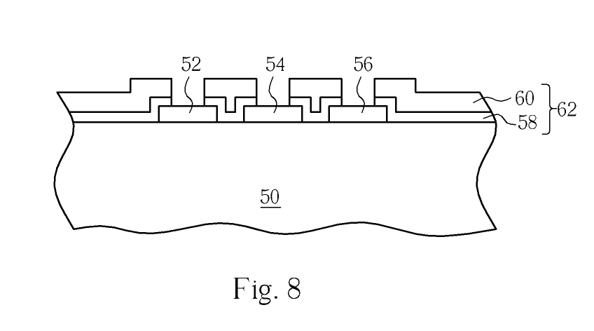

Please refer to FIG. 8 to FIG. 10. FIG. 8 to FIG. 10 are schematic diagrams for illustrating a method for manufacturing gold bumps according to a second embodiment of the present invention. The difference between the first and the second embodiments is that in the second embodiment a portion of a protective layer is removed by utilizing a first mask that is different from a second mask, the second mask being utilized in a gold bumping process. If the step of removing a portion of the protective layer is performed in foundries, foundries need to prepare the first mask. However, since this mask is not made for each individual gold bump position and only needs a simple pattern, its cost is lower. Thus, compared to the benefits received from improving the step height of the gold bump border, investing in this mask is very worthwhile.

As shown in FIG. 8, a substrate 50 is provided. The substrate 50 surface includes a plurality of bonding pads 52, 54, and 56, a silicon oxide layer 58, and a silicon nitride layer 60. The bonding pad 52, 54, and 56 are made of aluminum. The silicon oxide layer 58 and the silicon nitride layer 60 form a patterned protective layer 62, and the protective layer 62 covering the bonding pads 52, 54, and 56 is a raised protective layer 62 exposing a portion of surfaces of the bonding pads 52, 54, and 56. The silicon oxide layer 58 and the silicon nitride layer 60 are deposited on the substrate 50 and the surface of the bonding pads 52, 54, and 56 respectively. In the present invention, the thickness of the protective layer 62, composed of the silicon oxide layer 58 and the silicon nitride layer 60, covering the bonding pads 52, 54, and 56 is equivalent to the thickness of the protective layer 62 covering the substrate 50 surface.

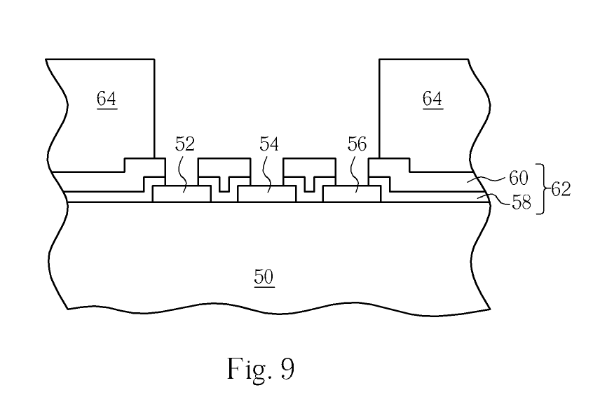

As shown in FIG. 9, a photo resist 64 covers the substrate 50 surface by a spin-on coating. Through a photolithography process such as exposing, developing, and so forth, the photo resist 64 is patterned by a first mask (not shown) to expose a portion of the raised protective layer 62 surface and the surface of the bonding pads 52, 54, and 56.

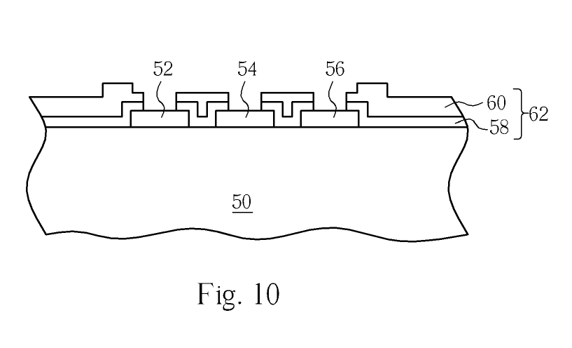

As shown in FIG. 10, utilizing the photo resist 64 as a mask, a portion of the protective layer 62 is removed by an etch process such as a wet etch process, dry etch process, and so forth. For example, a portion of the silicon nitride layer 60 is removed vertically. Therefore, a thickness of the protective layer covering the bonding pads 52, 54, and 56 is reduced. Afterward the photo resist 64 is removed. The following processes are similar to the processes in the first embodiment except a second mask different than the first mask is used in a gold bumping process, so unnecessary details are not given here.

In comparison with the prior art, the present invention is capable of shrinking the step height of the gold bump border, the bonding result between the gold bump and the package substrate is better and thus the package quality is increased substantially. Moreover, the present invention does not need to add an additional mask and increase the cost of the additional mask, or alternatively only needs a simple and low cost mask to perform the step of removing a portion of a protective layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing gold bumps, comprising:
providing a substrate comprising at least a bonding pad and a patterned protective layer, which exposes a portion of the bonding pad surface, on a surface of the substrate;
forming a first photo resist covering the surface of the substrate;
utilizing a mask to perform a photolithography process for patterning the first photo resist and exposing a portion of the protective layer and the bonding pad;
removing a portion of the protective layer to make a thickness of the protective layer covering the bonding pad smaller than a thickness of the protective layer covering the substrate surface;
removing the first photo resist; and
utilizing the mask to perform a gold bumping process.

2. The method for manufacturing gold bumps of claim 1, wherein the protective layer is composed of a silicon oxide layer and a silicon nitride layer covering the silicon oxide layer.

3. The method for manufacturing gold bumps of claim 1, wherein the thickness of the protective layer covering the bonding pad is equivalent to the thickness of the protective layer covering the substrate surface before removing a portion of the protective layer.

4. The method for manufacturing gold bumps of claim 1, wherein the bonding pad is made of aluminum (Al).

5. The method for manufacturing gold bumps of claim 1, wherein the step of removing a portion of the protective layer utilizes a wet etch process.

6. The method for manufacturing gold bumps of claim 1, wherein the step of removing a portion of the protective layer utilizes a dry etch process.

7. The method for manufacturing gold bumps of claim 1, wherein the gold bumping process comprises:
performing an under bump metallurgy process to form a metal layer on the substrate surface;
forming a second photo resist on the substrate surface;
utilizing the mask to perform a photolithography process for patterning the second photo resist on the substrate surface;
utilizing the second photo resist as a mask to form at least a gold bump on the substrate surface corresponding to the bonding pad;
removing the second photo resist;
removing portions of the metal layer that are not covered by the gold bump; and
performing a thermal anneal process.

8. The method for manufacturing gold bumps of claim 7, wherein the metal layer is composed of a titanium tungsten alloy (TiW alloy) layer and a gold (Au) layer.

9. The method for manufacturing gold bumps of claim 7, wherein the gold bump is made of gold (Au).

10. A method for manufacturing gold bumps, comprising:
providing a substrate that comprises a patterned protective layer and a plurality of bonding pads on a surface of the substrate, the protective layer covering the bonding pads being a raised protective layer exposing a portion of surfaces of the bonding pads;
forming a first photo resist covering the surface of the substrate;
utilizing a first mask to perform a photolithography process for patterning the first photo resist and exposing a portion of the raised protective layer and the bonding pads;
removing a portion of the protective layer to reduce a thickness of the protective layer covering the bonding pads;
removing the first photo resist; and
utilizing a second mask to perform a gold bumping process.

11. The method for manufacturing gold bumps of claim 10, wherein the protective layer is composed of a silicon oxide layer and a silicon nitride layer covering the silicon oxide layer.

12. The method for manufacturing gold bumps of claim 10, wherein the bonding pads are made of aluminum (Al).

13. The method for manufacturing gold bumps of claim 10, wherein the step of removing a portion of the protective layer utilizes a wet etch process.

14. The method for manufacturing gold bumps of claim 10, wherein the step of removing a portion of the protective layer utilizes a dry etch process.

15. The method for manufacturing gold bumps of claim 10, wherein the gold bumping process comprises:
performing an under bump metallurgy process to form a metal layer on the substrate surface;
forming a second photo resist on the substrate surface;
utilizing the second mask to perform a photolithography process for patterning the second photo resist on the substrate surface;
utilizing the second photo resist as a mask to form a plurality of gold bumps on the substrate surface corresponding to the bonding pads;
removing the second photo resist;
removing portions of the metal layer that are not covered by the gold bumps; and
performing a thermal anneal process.

16. The method for manufacturing gold bumps of claim 15, wherein the metal layer is composed of a titanium tungsten alloy (TiW alloy) layer and a gold (Au) layer.

17. The method for manufacturing gold bumps of claim 15, wherein the gold bumps are made of gold (Au).
